(19) United States
(12) Patent Application Publication
(10) Pub. No.: US 2024/0290835 A1
(43) Pub. Date: Aug. 29, 2024

(54) NANORIBBON-BASED TRANSISTORS WITH ETCH STOP LAYER TO ASSIST SUBFIN REMOVAL

(71) Applicant: Intel Corporation, Santa Clara, CA (US)

(72) Inventors: Chiao-Ti Huang, Portland, OR (US); Guowei Xu, Portland, OR (US); Tao Chu, Portland, OR (US); Robin Chao, Portland, OR (US); Jaladhi Mehta, Beaverton, OR (US); Brian Greene, Portland, OR (US); Chung-Hsun Lin, Portland, OR (US)

(73) Assignee: Intel Corporation, Santa Clara, CA (US)

(21) Appl. No.: 18/174,007

(22) Filed: Feb. 24, 2023

(51) Int. Cl. H01L 29/06; H01L 21/8234; H01L 27/088; H01L 29/40; H01L 29/423; H01L 29/786

(52) U.S. Cl. CPC H01L 29/0673; H01L 21/823412; H01L 27/0886; H01L 29/401; H01L 29/42392; H01L 29/78696

(57) ABSTRACT

Fabrication methods that employ an etch stop layer to assist subfin removal during fabrication of nanoribbon-based transistors are disclosed. An example fabrication method includes providing a stack of nanoribbons above a subfin, where the nanoribbons and the subfin include one or more semiconductor materials; depositing an etch stop layer over a top of the subfin and around portions of the nanoribbons; removing the etch stop layer from around the portions of the nanoribbons; providing a gate dielectric material around the portions of the nanoribbons and over the etch stop layer over the top of the subfin; depositing a gate electrode material around the portions of the nanoribbons; and performing an etch to remove the subfin without substantially removing the etch stop layer.

### BACKGROUND

For the past several decades, the scaling of features in integrated circuit (IC) structures has been a driving force behind an ever-growing semiconductor industry. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity. The drive for the ever-increasing capacity, however, is not without issue. The necessity to optimize every portion of an IC structure becomes increasingly significant.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 provides a perspective view of an example nanoribbon-based field-effect transistor (FET), according to some embodiments of the present disclosure.

FIG. 2 is a flow diagram of an example method of fabricating an IC structure with nanoribbon-based transistors using an etch stop layer to assist subfin removal, in accordance with some embodiments.

FIGS. 3A-3N provide cross-sectional side views at various stages in the fabrication of an example IC structure with nanoribbon-based transistors and an etch stop layer that was used to assist subfin removal according to the method of FIG. 2, in accordance with some embodiments.

FIG. 4 is a top view of a wafer and dies that may include any of the IC structures disclosed herein, in accordance with any of the embodiments disclosed herein.

FIG. 5 is a side, cross-sectional view of an IC device that may include any of the IC structures disclosed herein, in accordance with any of the embodiments disclosed herein.

FIG. 6 is a side, cross-sectional view of an IC package that may include any of the IC structures disclosed herein, in accordance with various embodiments.

FIG. 7 is a side, cross-sectional view of an IC device assembly that may include any of the IC structures disclosed herein, in accordance with any of the embodiments disclosed herein.

FIG. 8 is a block diagram of an example electrical device that may include any of the IC structures disclosed herein, in accordance with any of the embodiments disclosed herein.

### DETAILED DESCRIPTION

The systems, methods and devices of this disclosure each have several innovative aspects, no single one of which is solely responsible for all desirable attributes disclosed herein. Details of one or more implementations of the subject matter described in this specification are set forth in the description below and the accompanying drawings.

For purposes of illustrating nanoribbon-based transistors with etch stop layer to assist subfin removal, described herein, it might be useful to first understand phenomena that may come into play during IC fabrication. The following foundational information may be viewed as a basis from which the present disclosure may be properly explained. Such information is offered for purposes of explanation only and, accordingly, should not be construed in any way to limit the broad scope of the present disclosure and its potential applications.

Non-planar transistors such as double-gate transistors, tri-gate transistors, FinFETs, and nanowire/nanoribbon/nanosheet transistors refer to transistors having a non-planar architecture. In comparison to a planar architecture where the transistor channel has only one confinement surface, a non-planar architecture is any type of architecture where the transistor channel has more than one confinement surfaces. A confinement surface refers to a particular orientation of the channel surface that is confined by the gate field. Non-planar transistors potentially improve performance relative to transistors having a planar architecture, such as single-gate transistors.

Nanoribbon-based transistors may be particularly advantageous for continued scaling of complementary metal-oxide-semiconductor (CMOS) technology nodes due to the potential to form gates on all four sides of a channel material (hence, such transistors are sometimes referred to as “gate all around” transistors). As used herein, the term “nanoribbon” refers to an elongated structure of a semiconductor material having a longitudinal axis parallel to a support structure (e.g., a substrate, a die, a chip, or a wafer) over which such a structure is built. Typically, a length of a such a structure (i.e., a dimension measured along the longitudinal axis, shown in the present drawings to be along the y-axis of an example x-y-z coordinate system) is greater than each of a width (i.e., a dimension measured along the x-axis of the example coordinate system shown in the present drawings) and a thickness/height (i.e., a dimension measured along the z-axis of the example coordinate system shown in the present drawings). In some settings, the terms “nanoribbon” or “nanosheet” have been used to describe elongated semiconductor structures that have a rectangular transverse cross-section (i.e., a cross-section in a plane perpendicular to the longitudinal axis of the structure), while the term “nanowire” has been used to describe similar elongated structures but with circular transverse cross-sections. In the present disclosure, the term “nanoribbon” is used to refer to all such nanowires, nanoribbons, and nanosheets, as well as elongated semiconductor structures with a longitudinal axis parallel to the support structures and with having transverse cross-sections of any geometry (e.g., transverse cross-sections in the shape of an oval or a polygon with rounded corners). A transistor may then be described as a “nanoribbon-based transistor” if the channel of the transistor is a portion of a nanoribbon, i.e., a portion around which a gate stack of a transistor may wrap around. The semiconductor material in the portion of the nanoribbon that forms a channel of a transistor may be referred to as a “channel material,” with source and drain (S/D) regions of a transistor provided on either side of the channel material.

Typically, nanoribbon-based transistor arrangements include stacks of nanoribbons, where each stack includes two or more nanoribbons stacked above one another, with a single gate stack that includes a work function material provided for an entire stack or multiple stacks. Optionally, the gate stack may also include a gate dielectric material around each nanoribbon. Such nanoribbon-based transistor arrangements may be fabricated by, first, providing a stack of alternating layers of first and second semiconductor materials over a support (e.g., a substrate, a die, a wafer, or a chip). The first semiconductor material is a material that will later form nanoribbons, while the second semiconductor material is a material that is etch-selective with respect to the first semiconductor material so that it may later be removed to separate different nanoribbons of a stack from one another. For example, the first semiconductor material may be silicon, while the second semiconductor material may be silicon germanium. In such a fabrication process, the first semiconductor material provides the bottom layer of the stack as well two or more layers above the bottom layer, alternating with layers of the second semiconductor material. The fabrication process further includes patterning the stack of alternating layers, as well as, possibly, an upper portion of the support into a fin to define the width of future nanoribbons. Sidewalls of a bottom portion of the fin are enclosed by an insulator material commonly referred to as a “shallow trench insulator” (STI) and such a bottom portion of the fin enclosed by the STI is commonly referred to as a “subfin,” similar to a subfin portion of fin-based transistors. The subfin may include the bottom layer of the first semiconductor material of the stack and an upper portion of the support over which the stack was provided. The fabrication process further includes removing the second semiconductor material from the fin to release nanoribbons formed by the fin portions of the first semiconductor material above the subfin. After the nanoribbons are released, a gate stack is provided around portions of the nanoribbons formed of the higher levels of the first semiconductor material, while the first semiconductor material in the subfin portion of the fin remains but does not serve as a part of the nanoribbon-based transistors.

Embodiments of the present disclosure are based on recognition that performance of IC structures with nanoribbon-based transistors may be improved if some or all of the subfin resulting from conventional fabrication approaches to forming nanoribbon-based transistors could be removed. In particular, inventors of the present disclosure realized that, since the subfin is formed of the first semiconductor material, it may increase parasitic capacitance and compromise performance of IC structures in terms of frequency and/or speed of operation. Inventors further realized that removing the subfin from under the stack of nanoribbons is not trivial and may easily result in drive degradation and undesirable threshold voltage shifts in nanoribbon-based transistors.

Disclosed herein are fabrication methods that employ an etch stop layer to assist subfin removal during fabrication of nanoribbon-based transistors. The methods are based on providing, after the nanoribbons have been released, an etch stop layer over the surface of the subfin and the insulator material surrounding sidewalls of the subfin. After that, the back side of the substrate on which the nanoribbons were formed may be thinned until the bottom of the subfin is exposed, and then an etch may be performed to remove some or all of the material of the subfin without substantially removing the insulator material surrounding the sidewalls of the subfin. The etch stop layer at the top of the subfin will then prevent the etch from damaging the nanoribbons because the etch will not be able to continue past the etch stop layer. Fabrication methods disclosed herein allow removing some or all of the subfin in a manner that may reduce or eliminate drive degradation and undesirable threshold voltage shifts in nanoribbon-based transistors.

An example fabrication method includes providing a stack of nanoribbons above a subfin, where the nanoribbons and the subfin include one or more semiconductor materials; depositing an etch stop layer over a top of the subfin and around portions of the nanoribbons; removing the etch stop layer from around the portions of the nanoribbons; providing a gate dielectric material around the portions of the nanoribbons and over the etch stop layer over the top of the subfin; depositing a gate electrode material around the portions of the nanoribbons; and performing an etch to remove the subfin without substantially removing the etch stop layer.

IC structures as described herein, in particular IC structures with nanoribbon-based transistors and an etch stop layer below the nanoribbons (i.e., the etch stop layer that was used to assist subfin removal according to the fabrication methods described herein), may be implemented in one or more components associated with an IC or/and between various such components. In various embodiments, components associated with an IC include, for example, transistors, diodes, power sources, resistors, capacitors, inductors, sensors, transceivers, receivers, antennas, etc. Components associated with an IC may include those that are mounted on IC or those connected to an IC. The IC may be either analog or digital and may be used in a number of applications, such as microprocessors, optoelectronics, logic blocks, audio amplifiers, etc., depending on the components associated with the IC. In some embodiments, IC structures as described herein may be included in a radio frequency IC (RFIC), which may, e.g., be included in any component associated with an IC of an RF receiver, an RF transmitter, or an RF transceiver, e.g., as used in telecommunications within base stations (BS) or user equipment (UE). Such components may include, but are not limited to, power amplifiers, low-noise amplifiers, RF filters (including arrays of RF filters, or RF filter banks), switches, upconverters, downconverters, and duplexers. In some embodiments, IC structures as described herein may be included in memory devices or circuits. In some embodiments, IC structures as described herein may be employed as part of a chipset for executing one or more related functions in a computer.

For purposes of explanation, specific numbers, materials and configurations are set forth in order to provide a thorough understanding of the illustrative implementations. However, it will be apparent to one skilled in the art that the present disclosure may be practiced without the specific details or/and that the present disclosure may be practiced with only some of the described aspects. In other instances, well-known features are omitted or simplified in order not to obscure the illustrative implementations. The terms “substantially,” “close,” “approximately,” “near,” and “about,” generally refer to being within +/−10% of a target value, e.g., within +/−5% of a target value, based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−10% of a target value, e.g., within +/−5% of a target value, based on the context of a particular value as described herein or as known in the art.

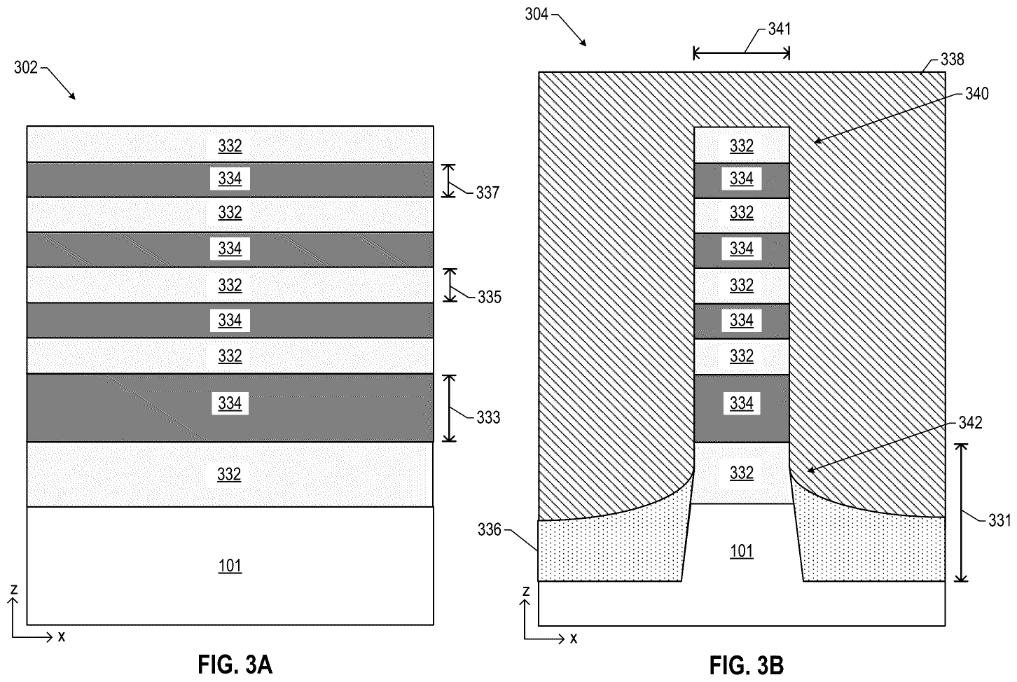

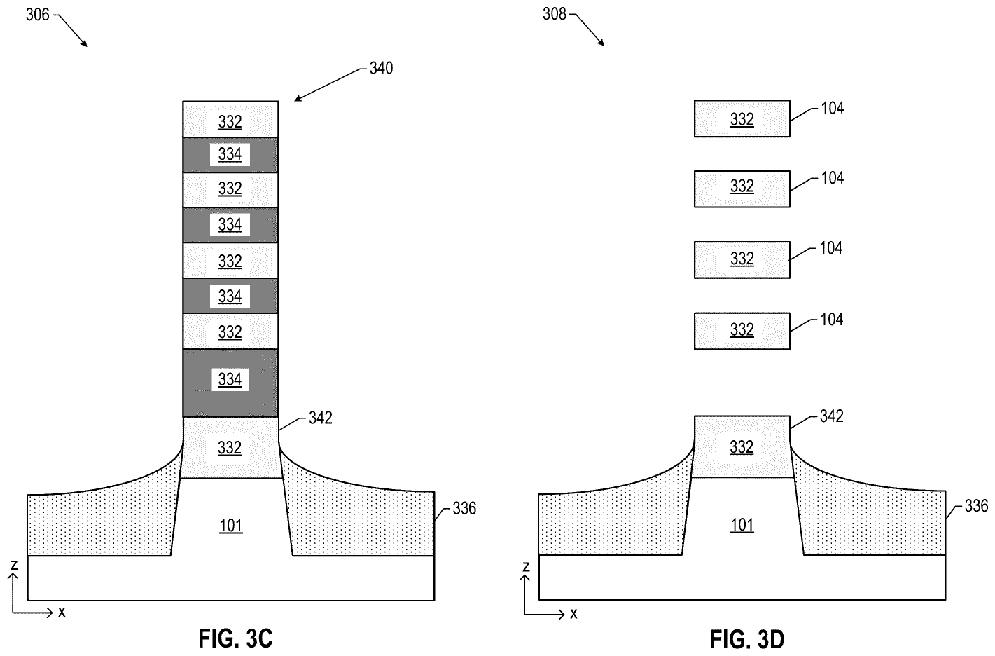

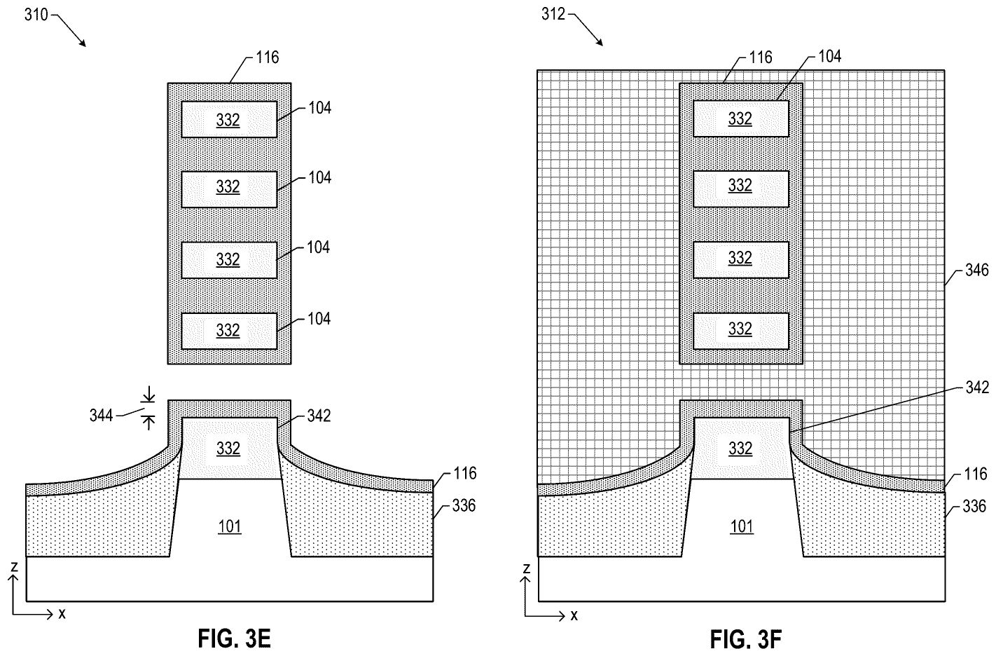

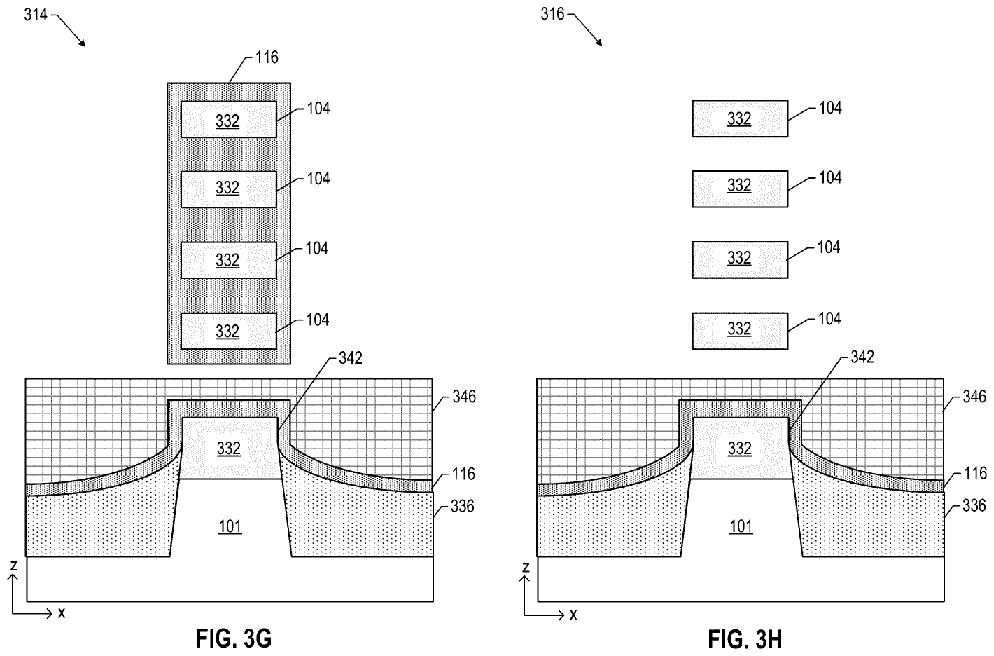

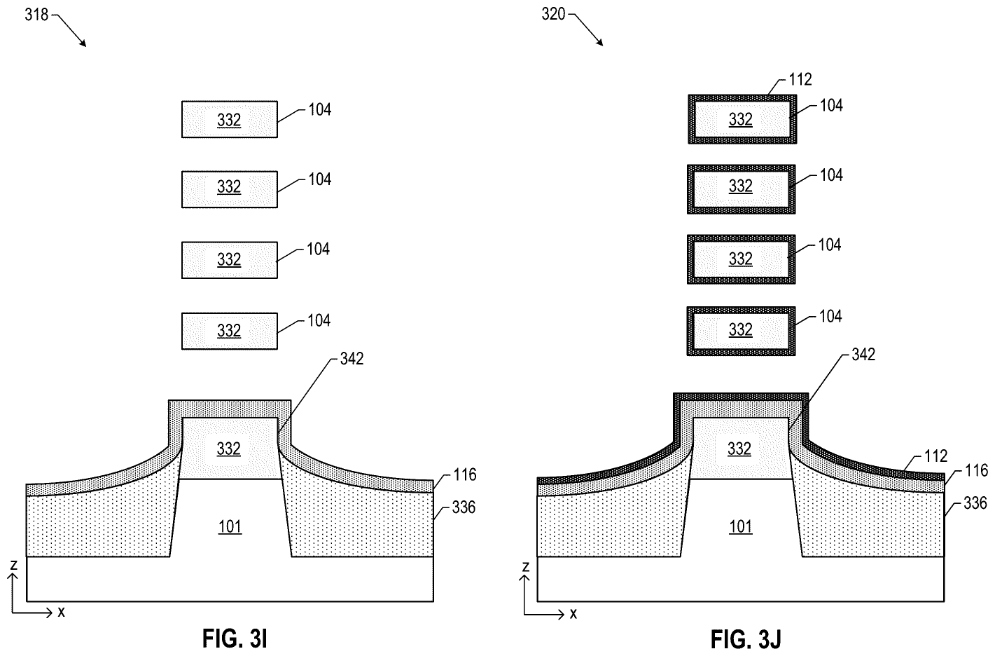

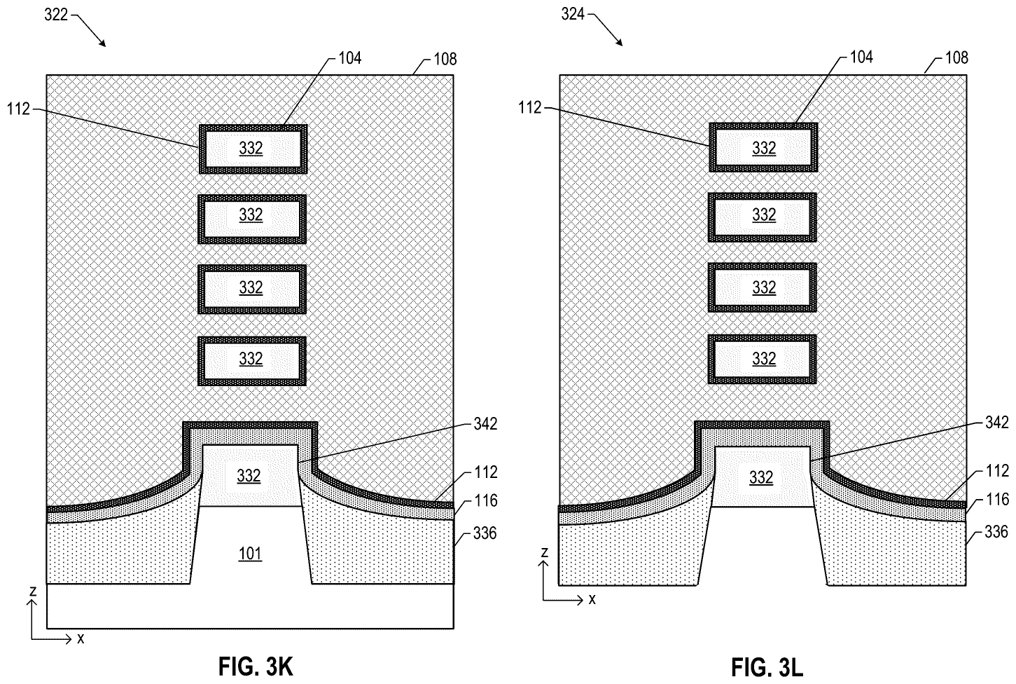

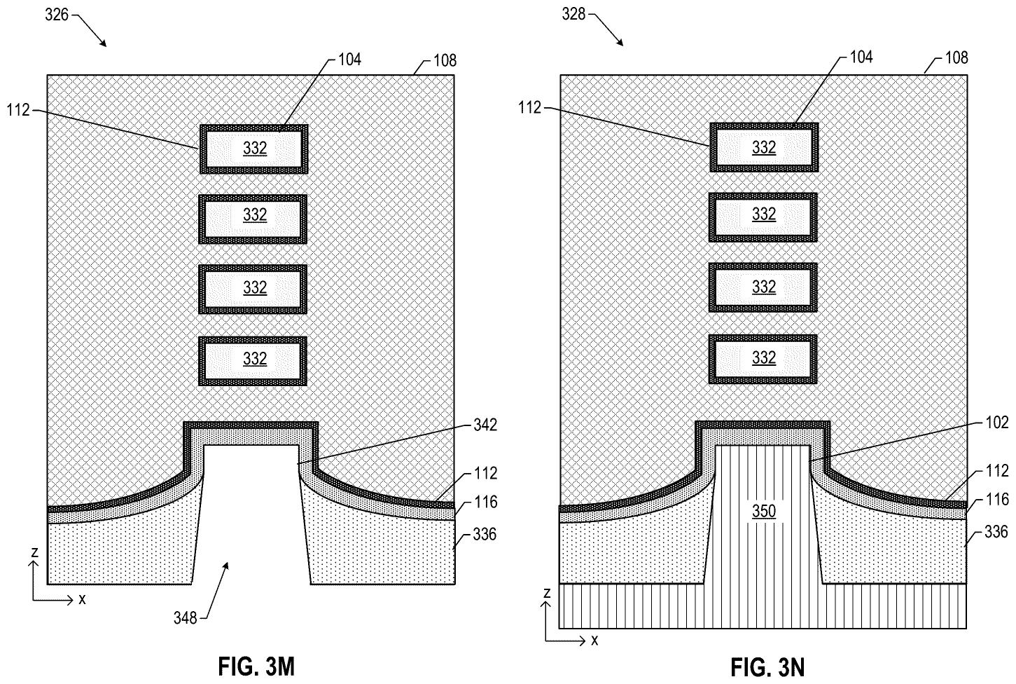

In the following description, references are made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense. For convenience, if a collection of drawings designated with different letters are present, e.g., FIGS. 3A-3N, such a collection may be referred to herein without the letters, e.g., as “FIG. 3.”

In the drawings, while some schematic illustrations of example structures of various devices and assemblies described herein may be shown with precise right angles and straight lines, this is simply for ease of illustration, and embodiments of these assemblies may be curved, rounded, or otherwise irregularly shaped as dictated by, and sometimes inevitable due to, the fabricating processes used to fabricate semiconductor device assemblies. Therefore, it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross-section of a device to detect the shape and the location of various device elements described herein using, e.g., Physical Failure Analysis (PFA) would allow determination of presence of nanoribbon-based transistors with an etch stop layer below the nanoribbons as described herein.

Various operations may be described as multiple discrete actions or operations in turn, in a manner that is most helpful in understanding the claimed subject matter. However, the order of description should not be construed as to imply that these operations are necessarily order dependent. These operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges.

The description uses the phrases “in an embodiment” or “in embodiments,” which may each refer to one or more of the same or different embodiments. The terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner. Although some materials may be described in singular form, such materials may include a plurality of materials, e.g., a semiconductor material may include two or more different semiconductor materials.

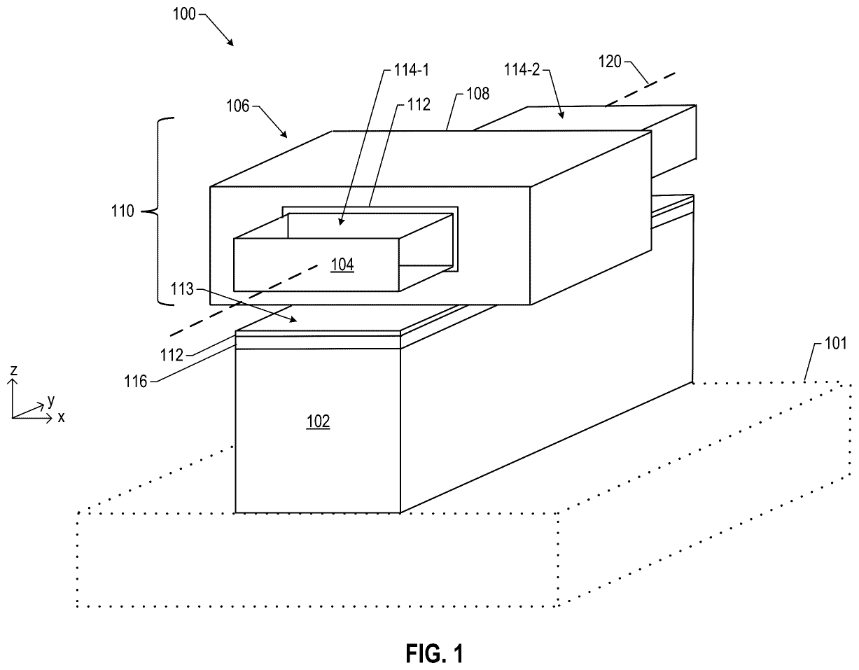

FIG. 1 provides a perspective view of an example IC structure 100 with a nanoribbon-based transistor 110 (in particular, a FET), according to some embodiments of the present disclosure. As shown in FIG. 1, the IC structure 100 includes a semiconductor material formed as a nanoribbon 104 extending substantially parallel to a support 101. The transistor 110 may be formed on the basis of the nanoribbon 104 by having a gate stack 106 wrap around at least a portion of the nanoribbon referred to as a “channel portion” and by having source and drain regions, shown in FIG. 1 as a first S/D region 114-1 and a second S/D region 114-2, on either side of the gate stack 106. One of the S/D regions 114 is a source region and the other one is a drain region. However, because, as is common in the field of FETs, designations of source and drain are often interchangeable, they are simply referred to herein as a first S/D region 114-1 and a second S/D region 114-2.

The nanoribbon 104 may take the form of a nanowire or nanoribbon, for example. In some embodiments, an area of a transversal cross-section of the nanoribbon 104 (i.e., an area in the x-z plane of the example coordinate system x-y-z shown in FIG. 1, perpendicular to a longitudinal axis 120 of the nanoribbon 104) may be between about 25 and 10000 square nanometers, including all values and ranges therein (e.g., between about 25 and 1000 square nanometers, or between about 25 and 500 square nanometers). In some embodiments, a width of the nanoribbon 104 (i.e., a dimension measured in a plane parallel to the support 101 and in a direction perpendicular to the longitudinal axis 120 of the nanoribbon 104, e.g., along the y-axis of the example coordinate system shown in FIG. 1) may be at least about 3 times larger than a height of the nanoribbon 104 (i.e., a dimension measured in a plane perpendicular to the support 101, e.g., along the z-axis of the example coordinate system shown in FIG. 1), including all values and ranges therein, e.g., at least about 4 times larger, or at least about 5 times larger. Although the nanoribbon 104 illustrated in FIG. 1 is shown as having a rectangular cross-section, the nanoribbon 104 may instead have a cross-section that is rounded at corners or otherwise irregularly shaped, and the gate stack 106 may conform to the shape of the nanoribbon 104. The term “face” of a nanoribbon may refer to the side of the nanoribbon 104 that is larger than the side perpendicular to it (when measured in a plane substantially perpendicular to the longitudinal axis 120 of the nanoribbon 104), the latter side being referred to as a “sidewall” of a nanoribbon.

In various embodiments, the semiconductor material of the nanoribbon 104 may be composed of semiconductor material systems including, for example, N-type or P-type materials systems. In some embodiments, the nanoribbon 104 may include a high mobility oxide semiconductor material, such as tin oxide, antimony oxide, indium oxide, indium tin oxide, titanium oxide, zinc oxide, indium zinc oxide, gallium oxide, titanium oxynitride, ruthenium oxide, or tungsten oxide. In some embodiments, the nanoribbon 104 may include a combination of semiconductor materials. In some embodiments, the nanoribbon 104 may include a monocrystalline semiconductor, such as silicon (Si) or germanium (Ge). In some embodiments, the nanoribbon 104 may include a compound semiconductor with a first sub-lattice of at least one element from group Ill of the periodic table (e.g., Al, Ga, In), and a second sub-lattice of at least one element of group V of the periodic table (e.g., P, As, Sb).

For some example N-type transistor embodiments (i.e., for the embodiments where the transistor 110 is an N-type metal-oxide-semiconductor (NMOS) transistor), the channel material of the nanoribbon 104 may include a III-V material having a relatively high electron mobility, such as, but not limited to InGaAs, InP, InSb, and InAs. For some such embodiments, the channel material of the nanoribbon 104 may be a ternary III-V alloy, such as InGaAs, GaAsSb, InAsP, or InPSb. For some InₓGa₁₋ₓAs fin embodiments, In content (x) may be between 0.6 and 0.9, and may advantageously be at least 0.7 (e.g., In_{0.7}Ga_{0.3}As). For some example P-type transistor embodiments (i.e., for the embodiments where the transistor 110 is a P-type metal-oxide-semiconductor (PMOS) transistor), the channel material of the nanoribbon 104 may advantageously be a group IV material having a high hole mobility, such as, but not limited to Ge or a Ge-rich SiGe alloy. For some example embodiments, the channel material of the nanoribbon 104 may have a Ge content between 0.6 and 0.9, and advantageously may be at least 0.7.

In some embodiments, the channel material of the nanoribbon 104 may be a thin-film material, such as a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. In general, if the transistor formed in the nanoribbon is a thin-film transistor (TFT), the channel material of the nanoribbon 104 may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, Nor P-type amorphous or polycrystalline silicon, germanium, indium gallium arsenide, silicon germanium, gallium nitride, aluminum gallium nitride, indium phosphite, and black phosphorus, each of which may possibly be doped with one or more of gallium, indium, aluminum, fluorine, boron, phosphorus, arsenic, nitrogen, tantalum, tungsten, and magnesium, etc. In some embodiments, the channel material of the nanoribbon 104 may have a thickness between about 5 and 75 nanometers, including all values and ranges therein. In some embodiments, a thin-film channel material may be deposited at relatively low temperatures, which allows depositing the channel material within the thermal budgets imposed on back end fabrication to avoid damaging other components, e.g., front end components such as the logic devices.

A gate stack 106 including a gate electrode material 108 and, optionally, a gate dielectric material 112, may wrap entirely or almost entirely around a portion of the nanoribbon 104 as shown in FIG. 1, with the active region (channel region) of the channel material of the transistor 110 corresponding to the portion of the nanoribbon 104 wrapped by the gate stack 106. As shown in FIG. 1, the gate dielectric material 112 may wrap around a transversal portion of the nanoribbon 104 and the gate electrode material 108 may wrap around the gate dielectric material 112.

The gate electrode material 108 may include at least one P-type work function metal or N-type work function metal, depending on whether the transistor 110 is a PMOS transistor or an NMOS transistor (P-type work function metal used as the gate electrode material 108 when the transistor 110 is a PMOS transistor and N-type work function metal used as the gate electrode material 108 when the transistor 110 is an NMOS transistor). For a PMOS transistor, metals that may be used for the gate electrode material 108 may include, but are not limited to, ruthenium, palladium, platinum, cobalt, nickel, and conductive metal oxides (e.g., ruthenium oxide). For an NMOS transistor, metals that may be used for the gate electrode material 108 include, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide). In some embodiments, the gate electrode material 108 may include a stack of two or more metal layers, where one or more metal layers are work function metal layers and at least one metal layer is a fill metal layer. Further layers may be included next to the gate electrode material 108 for other purposes, such as to act as a diffusion barrier layer or/and an adhesion layer.

In some embodiments, the gate dielectric material 112 may include one or more high-k dielectrics including any of the materials discussed herein with reference to the insulator material that may surround portions of the transistor 110. In some embodiments, an annealing process may be carried out on the gate dielectric material 112 during fabricate of the transistor 110 to improve the quality of the gate dielectric material 112. The gate dielectric material 112 may have a thickness that may, in some embodiments, be between about 0.5 nanometers and 3 nanometers, including all values and ranges therein (e.g., between about 1 and 3 nanometers, or between about 1 and 2 nanometers). In some embodiments, the gate stack 106 may be surrounded by a gate spacer, not shown in FIG. 1. Such a gate spacer would be configured to provide separation between the gate stack 106 and source/drain contacts of the transistor 110 and could be made of a low-k dielectric material, some examples of which have been provided above. A gate spacer may include pores or air gaps to further reduce its dielectric constant.

In some embodiments, e.g., when the transistor 110 is a storage transistor of a hysteretic memory cell (i.e., a type of memory that functions based on the phenomenon of hysteresis), the gate dielectric 112 may be replaced with, or complemented by, a hysteretic material. In some embodiments, a hysteretic material may be provided as a layer of a ferroelectric (FE) or an antiferroelectric (AFE) material. Such an FE/AFE material may include one or more materials that can exhibit sufficient FE/AFE behavior even at thin dimensions, e.g., such as an insulator material at least about 10% of which is in an orthorhombic phase or a tetragonal phase (e.g., as a material in which at most about 90% of the material may be amorphous or in a monoclinic phase). Some examples of such materials include materials that include hafnium, oxygen, and zirconium (e.g., hafnium zirconium oxide (HfZrO, also referred to as HZO)), materials that include hafnium, oxygen, and silicon (e.g., silicon-doped (Si-doped) hafnium oxide), materials that include hafnium, oxygen, and germanium (e.g., germanium-doped (Ge-doped) hafnium oxide), materials that include hafnium, oxygen, and aluminum (e.g., aluminum-doped (Al-doped) hafnium oxide), and materials that include hafnium, oxygen, and yttrium (e.g., yttrium-doped (Y-doped) hafnium oxide). However, in other embodiments, any other materials which exhibit FE/AFE behavior at thin dimensions may be used to replace, or to complement, the gate dielectric 112, and are within the scope of the present disclosure. The FE/AFE material included in the gate stack 106 may have a thickness that may, in some embodiments, be between about 0.5 nanometers and 10 nanometers, including all values and ranges therein (e.g., between about 1 and 8 nanometers, or between about 0.5 and 5 nanometers). In other embodiments, a hysteretic material may be provided as a stack of materials that, together, exhibit hysteretic behavior. Such a stack may include, e.g., a stack of silicon oxide and silicon nitride. Unless specified otherwise, descriptions provided herein with respect to the gate dielectric 112 are equally application to embodiments where the gate dielectric 112 is replaced with, or complemented by, a hysteretic material.

Turning to the S/D regions 114 of the transistor 110, in some embodiments, the S/D regions may be highly doped, e.g., with dopant concentrations of about 10²¹ cm⁻³, in order to advantageously form Ohmic contacts with the respective S/D electrodes, although these regions may also have lower dopant concentrations and may form Schottky contacts in some implementations. Irrespective of the exact doping levels, the S/D regions of a transistor are the regions having dopant concentration higher than in other regions, e.g., higher than a dopant concentration in the transistor channel (i.e., in a channel material extending between the first S/D region 114-1 and the second S/D region 114-2), and, therefore, may be referred to as “highly doped” (HD) regions. Even with doped to realize threshold voltage tuning as described herein, the channel portions of transistors typically include semiconductor materials with doping concentrations significantly smaller than those of the S/D regions 114.

The S/D regions 114 of the transistor 110 may generally be formed using either an implantation/diffusion process or an etching/deposition process. In the former process, dopants such as boron, aluminum, antimony, phosphorous, or arsenic may be ion-implanted into the nanoribbon 104 to form the source and drain regions. An annealing process that activates the dopants and causes them to diffuse further into the nanoribbon 104 may follow the ion implantation process. In the latter process, portions of the nanoribbon 104 may first be etched to form recesses at the locations of the future S/D regions 114. An epitaxial deposition process may then be carried out to fill the recesses with material that is used to fabricate the S/D regions 114. In some implementations, the S/D regions 114 may be fabricated using a silicon alloy such as silicon germanium or silicon carbide. In some implementations, the epitaxially deposited silicon alloy may be doped in situ with dopants such as boron, arsenic, or phosphorous. In further embodiments, the S/D regions 114 may be formed using one or more alternate semiconductor materials such as germanium or a group III-V material or alloy. And in further embodiments, one or more layers of metal and/or metal alloys may be used to form the S/D regions 114. In some embodiments, a distance between the first and second S/D regions 114 (i.e., a dimension measured along the longitudinal axis 120 of the nanoribbon 104) may be between about 5 and 40 nanometers, including all values and ranges therein (e.g., between about 22 and 35 nanometers, or between about 20 and 30 nanometers).

The IC structure 100 shown in FIG. 1, as well as IC structures shown in other drawings of the present disclosure, is intended to show relative arrangements of some of the components therein, and the IC structure 100, or portions thereof, may include other components that are not illustrated (e.g., electrical contacts to the S/D regions 114 of the transistor 110, additional layers such as a spacer layer around the gate electrode of the transistor 110, etc.). For example, although not specifically illustrated in FIG. 1, a dielectric spacer may be provided between a first S/D electrode (which may also be referred to as a “first S/D contact”) coupled to a first S/D region 114-1 of the transistor 110 and the gate stack 106 as well as between a second S/D electrode (which may also be referred to as a “second S/D contact”) coupled to a second S/D region 114-2 of the transistor 110 and the gate stack 106 in order to provide electrical isolation between the source, gate, and drain electrodes. In another example, although not specifically illustrated in FIG. 1, at least portions of the transistor 110 may be surrounded in an insulator material, such as any suitable interlayer dielectric (ILD) material. In some embodiments, such an insulator material may be a high-k dielectric including elements such as hafnium, silicon, oxygen, titanium, tantalum, lanthanum, aluminum, zirconium, barium, strontium, yttrium, lead, scandium, niobium, and zinc. Examples of high-k materials that may be used for this purpose may include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. In other embodiments, the insulator material surrounding portions of the transistor 110 may be a low-k dielectric material. Some examples of low-k dielectric materials include, but are not limited to, silicon dioxide, carbon-doped oxide, silicon nitride, organic polymers such as perfluorocyclobutane or polytetrafluoroethylene, fused silica glass (FSG), and organosilicates such as silsesquioxane, siloxane, or organosilicate glass.

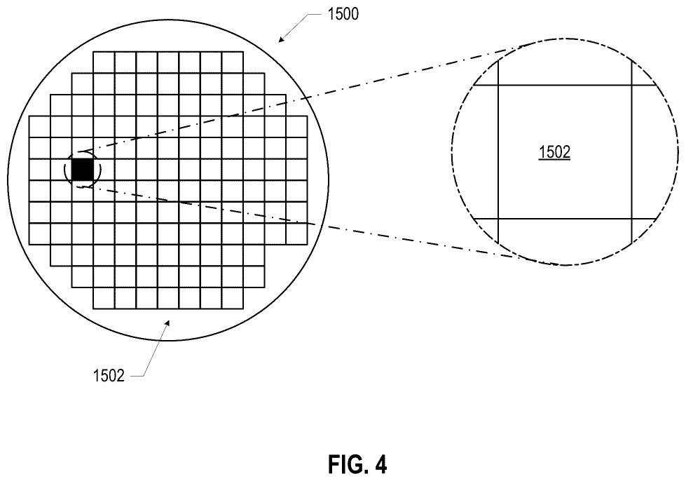

Implementations of the present disclosure may be formed or carried out on any suitable support structure, such as a substrate, a die, a wafer, or a chip. The support structure may, e.g., be the wafer 1500 of FIG. 4, discussed below, and may be, or be included in, a die, e.g., the singulated die 1502 of FIG. 4, discussed below. The support structure may be a semiconductor substrate composed of semiconductor material systems including, for example, N-type or P-type materials systems. In one implementation, the semiconductor substrate may be a crystalline substrate formed using a bulk silicon or a silicon-on-insulator (SOI) substructure. In other implementations, the semiconductor substrate may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-V materials (i.e., materials from groups III and V of the periodic system of elements), group II-VI (i.e., materials from groups II and IV of the periodic system of elements), or group IV materials (i.e., materials from group IV of the periodic system of elements). In some embodiments, the substrate may be non-crystalline. In some embodiments, the support structure may be a printed circuit board (PCB) substrate. Although a few examples of materials from which the support structure may be formed are described here, any material that may serve as a foundation upon which an IC structure with nanoribbon-based transistors and an etch stop layer below the nanoribbons as described herein may be built falls within the spirit and scope of the present disclosure.

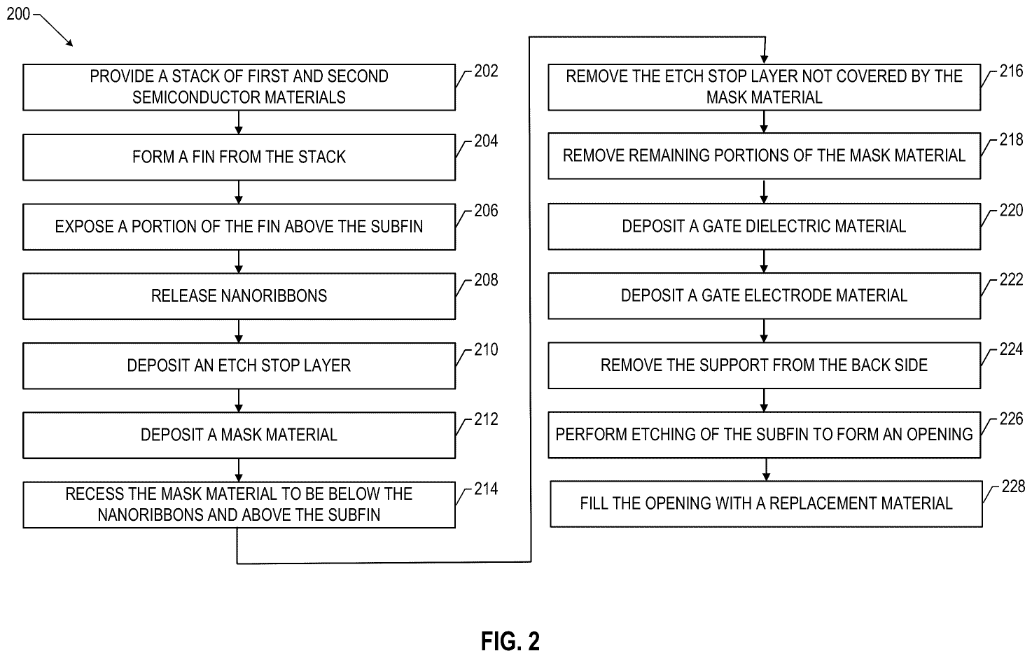

As further shown in FIG. 1, the IC structure 100 includes a replacement structure 102 between the transistor 110 and the support 101. The replacement structure 102 may be what was originally a subfin made of the semiconductor material of the nanoribbon 104 and, optionally, of an upper portion of the support 101, which subfin was removed as a part of implementing a fabrication method that involved using an etch stop layer to assist subfin removal as described herein (e.g., a fabrication method 200 shown in FIG. 2). An opening in the IC structure 100 formed by the removal of the subfin may subsequently be filled with any suitable material, e.g., an insulator material, thus forming the replacement structure 102. Characteristic of the use of the fabrication method described herein is an etch stop layer 116 present between the replacement structure 102 and the nanoribbon 104, as shown in FIG. 1. If the gate stack 106 of the transistor 110 includes a gate dielectric material 112, as is shown in FIG. 1, then an additional layer 113 of the gate dielectric material 112 may also be present below the gate stack 106, e.g., between the etch stop layer 116 and the gate stack 106, so that the etch stop layer 116 is between the replacement structure 102 and the additional layer of the gate dielectric material 112 that is below the gate stack 106. Presence of the additional layer 113 of the gate dielectric material 112 is also characteristic of the use of the fabrication method described herein.

The support 101 is shown in FIG. 1 with a dotted outline to illustrate that, in one scenario, it may be a support structure as described above over which the nanoribbon 104 may be originally provided. In such a scenario, the dotted outline of the support 101 represents that, as a result of a fabrication method that uses the etch stop layer 116 to assist subfin removal as described herein (e.g., with reference to FIG. 2), the original support structure is later removed and the support 101 is absent from the IC structure 100. In another scenario, the dotted outline of the support 101 is used to represent that the support 101 may be any other structure to which the transistor 110 and the replacement structure 102 may be attached after the original support structure is removed and the subfin is replaced with the replacement structure 102 as a part of the fabrication method described herein. For example, in some embodiments according to this scenario, the support 101 may be a carrier substrate, a package substrate, an interposer, or another die.

Although only one nanoribbon 104 is shown in FIG. 1, the IC structure 100 may include a plurality of such nanoribbons 104 stacked above one another, e.g., as is shown in FIG. 3N showing an IC structure 328 which may be one example of the IC structure 100.

FIG. 2 is a flow diagram of an example method 200 of fabricating an IC structure with nanoribbon-based transistors using an etch stop layer to assist subfin removal, in accordance with some embodiments. Although the operations of the method 200 are illustrated once each and in a particular order, the operations may be performed in any suitable order and repeated as desired. For example, one or more operations may be performed in parallel to fabricate multiple IC structures with nanoribbon-based transistors substantially simultaneously. In another example, the operations may be performed in a different order to reflect the structure of an IC device in which with nanoribbon-based transistors and an etch stop layer below the nanoribbons will be implemented.

In addition, the example fabricating method 200 may include other operations not specifically shown in FIG. 2, such as various cleaning or planarization operations as known in the art. For example, in some embodiments, the support 101, as well as layers of various other materials subsequently deposited thereon, may be cleaned prior to, after, or during any of the processes of the method 200 described herein, e.g., to remove oxides, surface-bound organic and metallic contaminants, as well as subsurface contamination. In some embodiments, cleaning may be carried out using e.g., a chemical solutions (such as peroxide), and/or with ultraviolet (UV) radiation combined with ozone, and/or oxidizing the surface (e.g., using thermal oxidation) then removing the oxide (e.g., using hydrofluoric acid (HF)). In another example, the intermediate IC structures described herein may be planarized prior to, after, or during any of the processes of the method 200 described herein, e.g., to remove overburden or excess materials. In some embodiments, planarization may be carried out using either wet or dry planarization processes, e.g., planarization be a chemical mechanical planarization (CMP), which may be understood as a process that utilizes a polishing surface, an abrasive and a slurry to remove the overburden and planarize the surface.

FIGS. 3A-3N provide cross-sectional side views at various stages in the fabrication of an example IC structure with nanoribbon-based transistors and an etch stop layer below the nanoribbons according to the method 200 of FIG. 2, in accordance with some embodiments. Each of FIGS. 3A-3N provides a cross-sectional side view in the x-z plane of the example coordinate system shown in FIG. 1).

The method 200 may begin with a process 202 that includes providing alternate layers of first and second semiconductor materials in a stack. An IC structure 302 of FIG. 3A illustrates an example result of the process 202. The IC structure 302 includes a support 101 and alternate layers of a first semiconductor material 332 and a second semiconductor material 334, where different layers are labeled in FIG. 3A with reference numerals after the dash after the reference numeral of a given semiconductor material. While FIG. 3A illustrates five layers of the first semiconductor material 332 (labeled as layers 332-1 through 332-5) and four layers of the second semiconductor material 334 (labeled as layers 334-1 through 334-4), in other embodiments, any other number of layers may be used as long as they are alternating and include at least three layers of the first semiconductor material 332 and at least two layers of the second semiconductor material 334. The upper layers of the first semiconductor material 332 will later be formed into nanoribbons 104 stacked above one another. Thus, although a particular number of nanoribbons 104 formed of the upper layers of the first semiconductor material 332 is depicted in FIG. 3D (namely, four nanoribbons 104) and subsequent drawings, embodiments of the present disclosure include IC structures having more or fewer stacked nanoribbons 104 than depicted. As shown in FIG. 3A, in some embodiments, the alternation of layers of the first semiconductor material 332 and the second semiconductor material 334 may begin after, first, a bottom layer of the first semiconductor material 332 (i.e., the layer 332-1) is provided over the support 101.

The first semiconductor material 332 may be any of the semiconductor/channel materials described above with reference to the nanoribbon 104. The second semiconductor material 334 may be any suitable material that is etch-selective with respect to the first semiconductor material 332 so that, in a later process, the second semiconductor material 334 may be etched away to form nanoribbons of the first semiconductor material 332. As known in the art, two materials are said to be “etch-selective” (or said to have “sufficient etch selectivity”) with respect to one another when etchants used to etch one material do not substantially etch the other, enabling selective etching of one material but not the other. For example, in some embodiments, the first semiconductor material 332 may be silicon while the second semiconductor material 334 may be silicon germanium. It should be noted that while the present disclosure refers to the second semiconductor material 334, descriptions provided herein are equally applicable to the layers shown as layers of the second semiconductor material 334 being made of a non-semiconductor material, e.g., of an insulator material, as long as this material is sufficiently etch-selective with respect to the first semiconductor material 332. Thus, material 334 may be any suitable sacrificial material that is etch-selective with respect to the first semiconductor material 332. Selecting the material 334 to be a semiconductor material may be particularly advantageous because it may improve quality of the first semiconductor material 332 if the first semiconductor material 332 is epitaxially grown on the material 334. Thus, in some embodiments, the process 202 may include epitaxially growing layers of the first semiconductor material 332 and the second semiconductor material 334 in an alternating manner. In other embodiments, alternate layers of the first semiconductor material 332 and the second semiconductor material 334 may be provided in the process 202 using other techniques, such as layer transfer or thin-film deposition. Although FIG. 3A illustrates the same first semiconductor material 332 in various layers of the IC structure 302, in general, material compositions of a semiconductor material from which nanoribbons 104 will later be formed in different layers of the IC structure 302 may be different. For example, the first semiconductor material 332 of one layer of the IC structure 302 may be silicon while the first semiconductor material 332 of another layer of the IC structure 302 may be a III-N semiconductor material such as GaN.

In some embodiments, a thickness 333 of the bottom layer of the second semiconductor material 334 may be greater than a thickness 337 of subsequent layers of the second semiconductor material 334, which may be advantageous in terms of enlarging the process window for hard mask to recess between the bottom nanowire and the subfin. For example, the thickness 333 may be between about 5 and 80 nanometers. On the other hand, the thickness 337 may be between about 5 and 30 nanometers. A thickness 335 of various layers of the first semiconductor material 332 may be that of the thickness of the nanoribbons 104, e.g., between about 5 and 75 nanometers.

The method 200 may then proceed with a process 204 that includes forming the stack of alternate layers of first and second semiconductor materials into a fin. An IC structure 304 of FIG. 3B illustrates an example result of the process 204, showing that a stack of the first and second semiconductor materials 332, 334 has been patterned as a fin 340. The fin 340 may be shaped as a structure that extends away from the support 101 and may include a subfin 342 at the bottom, the subfin 342 being a portion of the fin 340 that is enclosed by an insulator material 336. The insulator material 336 may enclose sidewalls of the subfin 342 of the fin 340, and may include any suitable insulator material, e.g., any of the insulator materials described herein. In some embodiments, the subfin 342 may include the bottom layer of the first semiconductor material 332 deposited at 202 as well as an upper portion of the support 101, as is shown in FIG. 3B and the subsequent drawings. However, in other embodiments, the subfin 342 may include only the first semiconductor material 332 and not any portions of the support 101 (not shown in the present drawings). In various embodiments, a height 331 of the subfin 342 (i.e., a dimension measured along the z-axis of the example coordinate system shown) may be between about 10 and 100 nanometers. In some embodiments, the fin 340 may have a width 341 (i.e., a dimension measured along the x-axis of the example coordinate system shown). The width 341 may be that of the width of the nanoribbons 104, e.g., described above. The fin 340 may further have a length (i.e., a dimension measured along the y-axis of the example coordinate system shown) suitable to account for the length of the future nanoribbons (e.g., as described above with reference to the length of the nanoribbon 104). In various embodiments, any suitable patterning techniques may be used in the process 204 to form the fin 340, such as, but not limited to, photolithographic or electron-beam (e-beam) patterning, possibly in conjunction with a suitable etching technique, e.g., a dry etch, such as e.g., radio frequency (RF) reactive ion etch (RIE) or inductively coupled plasma (ICP) RIE. In some embodiments, the etch performed in the process 204 may include an anisotropic etch, using etchants in a form of e.g., chemically active ionized gas (i.e., plasma) using e.g., bromine (Br) and chloride (CI) based chemistries. In some embodiments, during the etch of the process 204, the IC structure may be heated to elevated temperatures, e.g., to temperatures between about room temperature and 200 degrees Celsius, including all values and ranges therein, to promote that byproducts of the etch are made sufficiently volatile to be removed from the surface.

The IC structure 304 further illustrates a further material 338. The further material 338 may represent a replacement metal gate as known in the art and may include any suitable materials, such as polysilicon.

The method 200 may then proceed with a process 206 that includes exposing a portion of the fin where the gate will be formed, i.e., exposing a portion of the fin above the subfin portion. An IC structure 306 of FIG. 3C illustrates an example result of the process 206, showing that the further material 338 is removed to expose a portion of the fin 340 where the gate will be formed, i.e., to expose a portion above the subfin 342. FIG. 3C further shows that the insulator material 336 is recessed to be below the bottom layer of the second semiconductor material 334. Any kind of suitable etching techniques may be used to realize the process 206, such as any of the etching techniques described above. For an example, an etching may be done using etchants that can remove the further material 338 without substantially removing the first and second semiconductor material 332, 334.

The method 200 may then include a process 208, in which the second semiconductor material is removed to release the nanoribbons. An IC structure 308 shown in FIG. 3D illustrates an example result of the process 208, showing that the second semiconductor material 334 is removed in the gate portion of the fin 340, thus releasing the nanoribbons 104 of the first semiconductor material 332, stacked above one another. When the first semiconductor material 332 and the second semiconductor material 334 are sufficiently etch-selective with respect to one another, removing the second semiconductor material 334 (e.g., SiGe) of the fin 340 in the process 208 may include etching the second semiconductor material 334, e.g., using anisotropic etching, without substantially etching the first semiconductor material 332 (e.g., Si). As a result of removing the second semiconductor material 334, the subfin 342 is now separated from the nanoribbons 104 of the first semiconductor material 332.

Processes 202-208 of the method 200 provide one example of how a stack of released nanoribbons with gate regions exposed for providing a gate metal may be fabricated. In other embodiments, other processes known in the art for providing a stack of released nanoribbons may be used, e.g., any processes of replacement metal gate (RMG) techniques and are within the scope of the present disclosure. The nanoribbons may be described as “released” when openings are formed around channel portions of the nanoribbons, the openings defining areas where gate electrode materials are to be deposited.

The method 200 may then proceed with a process 210 that includes depositing an etch stop layer over all exposed surfaces of the IC structure resulting from the process 208. An IC structure 310 of FIG. 3E illustrates an example result of the process 210, showing an etch stop layer 216 deposited around exposed portions of the nanoribbons 104, as well as over the upper portion of the subfin 342 and over the top surface of the insulator material 336 surrounding the sidewalls of the subfin 342. A thickness 344 of the etch stop layer 116 provided over the upper portion of the subfin 342 and the insulator material 336 may be between about 1 and 10 nanometers, e.g., between about 1 and 5 nanometers, or between about 2 and 4 nanometers. Any suitable deposition technique may be used to deposit the etch stop layer 116 in the process 210, e.g., any suitable conformal deposition technique where the etch stop layer 116 is provided on all exposed surfaces. Examples of deposition techniques that may be used in the process 210 include atomic layer deposition (ALD), chemical vapor deposition (CVD), plasma enhanced CVD (PECVD), or/and physical vapor deposition (PVD) processes such as sputter. Because in a later process the etch stop layer 116 will need to be removed from the nanoribbons 104, material and deposition of the etch stop layer 116 may be selected as to provide no or sufficiently minimal damage to the nanoribbons 104 when the etch stop layer 116 is subsequently removed. For example, in some embodiments, the etch stop layer 116 may include a material comprising aluminum and oxygen (e.g., aluminum oxide). In other embodiments, the etch stop layer 116 may include a material comprising a metal and nitrogen (e.g., a metal nitride), e.g., a material comprising titanium and nitrogen (e.g., titanium nitride). In some embodiments, the process 210 may include performing an ozone treatment prior to depositing the etch stop layer 116. Performing an ozone treatment before depositing the etch stop layer 116 may oxidize the exposed surfaces of the first semiconductor material 332, which may later be removed together with the removal of the etch stop layer 116. In some embodiments, the process 210 may include performing an ozone treatment after depositing the etch stop layer 116. Performing an ozone treatment after depositing the etch stop layer 116 may oxidize the exposed surfaces of the etch stop layer 116, which oxide may later be removed together with the removal of the etch stop layer 116. In some embodiments, the process 210 may include performing an ozone treatment both before and after depositing the etch stop layer 116.

The method 200 may further include a process 212, in which a mask material is provided over the IC structure resulting from the process 210. An IC structure 312 shown in FIG. 3F illustrates an example result of the process 212, showing that a mask material 346 is provided over the IC structure 310. The mask material 346 may include any material that is sufficiently etch-selective with respect to the material of the etch stop layer 116 so that, in a later process, the etch stop layer 116 that is no longer covered by the mask material 346 may be removed without substantially removing anything covered by the mask material 346. The mask material 346 may also be sufficiently etch-selective with respect to the first semiconductor material 332 so that, in a later process, the mask material 346 may be removed without removing or damaging the first semiconductor material 332 of the nanoribbons 104. Any suitable process may include depositing the mask material 346, such as any of the deposition processes described above.

The method 200 may then include a process 214, in which the mask material provided in the previous process is recessed to expose nanoribbons while still covering the subfin 342 and the etch stop layer 116 that is on the subfin 342 and on the insulator material 336. An IC structure 314 shown in FIG. 3G illustrates an example result of the process 208, showing that the mask material 346 is recessed so that the nanoribbons 104 and the etch stop layer 116 surrounding the nanoribbons 104 are exposed, while the upper surface of the mask material 346 remains to be above the etch stop layer 116 on the subfin 342 and on the insulator material 336. This is where having the thickness 333 of the bottom layer of the second semiconductor material 334 greater than the thickness 337 of subsequent layers of the second semiconductor material 334, as described above (see FIG. 3A) may be particularly useful, providing a larger margin for error for recessing the mask material 346 far enough to be below the bottom nanoribbon 104, but not as far as to expose the etch stop layer 116 on the subfin 342. Any kind of suitable etching techniques may be used to recess the mask material 346 in the process 214, such as any of the etching techniques described above. When the mask material 346 and the etch stop layer 116 are sufficiently etch-selective with respect to one another, recessing the mask material 346 in the process 214 may include etching the mask material 346, e.g., using anisotropic etching, without substantially etching the etch stop layer 116 wrapping around the nanoribbons 104.

The method 200 may then proceed with a process 216 that includes removing the etch stop layer 116 not protected by the recessed mask material 346. An IC structure 316 of FIG. 3H illustrates an example result of the process 216, showing that the etch stop layer 116 is removed from the nanoribbons 104, while remaining in the portions of the IC structure 316 where the etch stop layer 116 is covered by the mask material 346. Again, when the mask material 346 and the etch stop layer 116 are sufficiently etch-selective with respect to one another, removing the etch stop layer 116 not protected by the mask material 346 in the process 216 may include etching the etch stop layer 116, e.g., using anisotropic etching, without substantially removing the etching the etch stop layer 116 protected by the mask material 346.

The method 200 may further include a process 218, in which the remainder of the mask material 346 is removed. An IC structure 318 of FIG. 3I illustrates an example result of the process 218, showing that the mask material 346 that was previously still covering the etch stop layer 116 that is on the subfin 342 and on the insulator material 336 is now removed. When the mask material 346 and the first semiconductor material 332 are sufficiently etch-selective with respect to one another, removing the mask material 346 in the process 218 may include etching the mask material 346, e.g., using anisotropic etching, without substantially etching the first semiconductor material 332 of the nanoribbons 104.

Next, the method 200 includes a process 220 of depositing a gate dielectric over exposed surfaces of the IC structure resulting from the process 218. An IC structure 320 of FIG. 3J illustrates an example result of the process 220, showing a gate dielectric material 112 deposited around exposed portions of the nanoribbons 104, as well as over the etch stop layer 116 on the upper portion of the subfin 342 and the top surface of the insulator material 336 surrounding the sidewalls of the subfin 342. The gate dielectric 112 deposited in the process 220 may be substantially as described above with reference to FIG. 1 and may be deposited using any suitable deposition technique, e.g., conformal deposition.

After the gate dielectric material, a gate electrode material may be deposited in a process 222 of the method 200. An IC structure 322 of FIG. 3K illustrates an example result of the process 222, showing a gate electrode material 108 deposited around gate dielectric material 112 of the IC structure 320. The gate electrode material 108 deposited in the process 222 may be substantially as described above with reference to FIG. 1 and may be deposited using any suitable deposition technique.

The method 200 may further include a process 224, in which the support 101 is removed to expose the back side of the first semiconductor material 332 of the subfin 342. An IC structure 324 of FIG. 3L illustrates an example result of the process 224, showing that the bottom portion of the support 101 as well as a portion of the support 101 within the subfin 342 is removed and the back side of the subfin 342 is exposed. The support 101 may be removed in the process 224 using a suitable thinning/polishing process, possibly in combination with an etching process (e.g., a thinning/polishing process may be used to remove a portion of the support 101 below the subfin 342, and an etching process may be used to remove a portion of the support 101 within the subfin 342). When the material of the support 101 and the insulator material 336 are sufficiently etch-selective with respect to one another, removing the support 101 within the subfin 342 in the process 224 may include etching the support 101, e.g., using anisotropic etching, without substantially etching the insulator material 336.

Removing the support 101 exposes the first semiconductor material 332 of the subfin 342, which may then be etched in a process 226 of the method 200. An IC structure 326 of FIG. 3M illustrates an example result of the process 226, showing that all of the first semiconductor material 332 of the subfin 342 may be removed, leaving an opening 348. When the first semiconductor material 332 and the insulator material 336 are sufficiently etch-selective with respect to one another, removing the first semiconductor material 332 of the subfin 342 in the process 226 may include etching the first semiconductor material 332, e.g., using anisotropic etching, without substantially etching the insulator material 336. Although FIG. 3M illustrates that the first semiconductor material 332 of the subfin 342 is removed completely, in some embodiments, only a portion of the first semiconductor material 332 of the subfin 342 may be removed and a portion may still remain. However, if a it is desired that all of the first semiconductor material 332 of the subfin 342 is removed using the etch of the process 226, the etch stop layer 116 that was on the upper portion of the subfin 342 and on the insulator material 336 will prevent the etch from going further and damaging the nanoribbons 104. Removing any portion of the first semiconductor material 332 of the subfin 342 may provide advantages in terms of reducing or eliminating drive degradation and undesirable threshold voltage shifts in nanoribbon-based transistors formed based on the nanoribbons 104 of the IC structure 326. Although processes 224 and 226 are described as separate processes where, first, the support 101 is removed, and then the first semiconductor material 332 of the subfin 342 is removed, in some embodiments, they may be combined in a single process in which the portion of the support 101 below the subfin 342 and the materials of the subfin 342 are removed (i.e., in such embodiments, the IC structure 322 resulting from the process 222 would be transformed into the IC structure 326 with the opening 348 as shown in FIG. 3M).

The method 200 may further include depositing a replacement material 350 in the opening 348 and, optionally, at the back side of the insulator material 336. An IC structure 328 of FIG. 3N illustrates an example result of the process 228, where the replacement material 350 in the opening 348 forms the replacement structure 102 as described with reference to FIG. 1. The IC structure 328 is one example of the IC structure 100, described above.

Performing the method 200 will result in several characteristic features in the IC structure 100/328 which would not be seen in IC structures with conventional nanoribbon-based transistors. For example, because the replacement material 350 is deposited to replace the subfin 342 of the fin 340 that was formed earlier in the method 200, the replacement structure 102 will be aligned with at least the bottom nanoribbon 104 of the stack of nanoribbon 104. Having a replacement structure 102 of an insulator material at the bottom of the nanoribbons 104 and substantially aligned in the direction of the x-axis is characteristic of the method 200. The replacement structure 102 may be seen as a trench in the insulator material 336, filled with an insulator material that may have same or different material composition.

The replacement structure 102 may extend along the entire length of the nanoribbons 104, as is seen in the perspective illustration of FIG. 1. Another characteristic feature is the presence of the etch stop layer 116 below the stack of the nanoribbons 104 and delineating the gate electrode material 108 on one side of the etch stop layer 116 and the replacement structure 102 and the insulator material 336 on the other side of the etch stop layer 116.

Nanoribbon-based transistors with etch stop layer as described herein (e.g., as described with reference to FIGS. 1-3) may be used to implement any suitable components. For example, in various embodiments, transistors described herein may be part of one or more of: a central processing unit, a memory device (e.g., a high-bandwidth memory device), a memory cell, a logic circuit, input/output circuitry, a field programmable gate array (FPGA) component such as an FPGA transceiver or an FPGA logic, a power delivery circuitry, an amplifier (e.g., a III-V amplifier), Peripheral Component Interconnect Express (PCIE) circuitry, Double Data Rate (DDR) transfer circuitry, a computing device (e.g., a wearable or a handheld computing device), etc.

The IC structures 100 disclosed herein may be included in any suitable electronic component. FIGS. 4-8 illustrate various examples of apparatuses that may include any of the IC structures 100 disclosed herein.

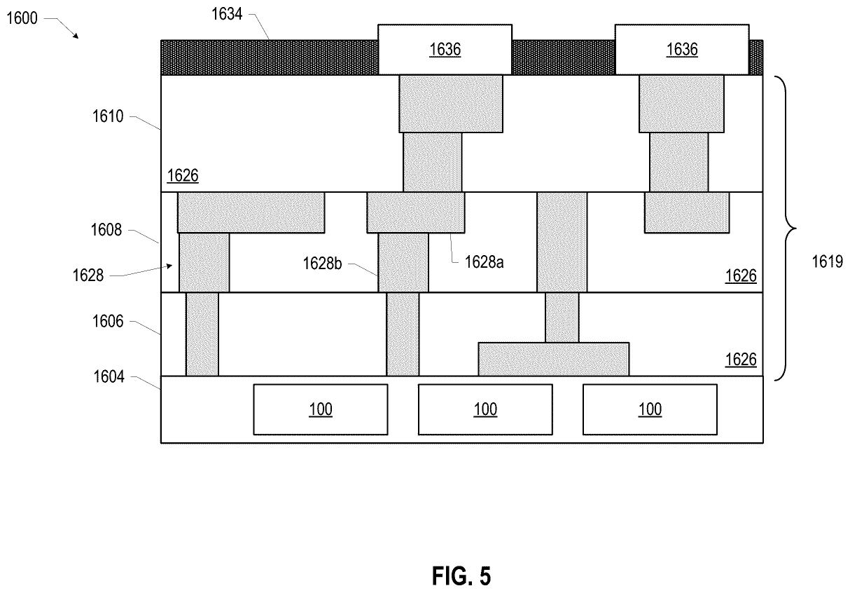

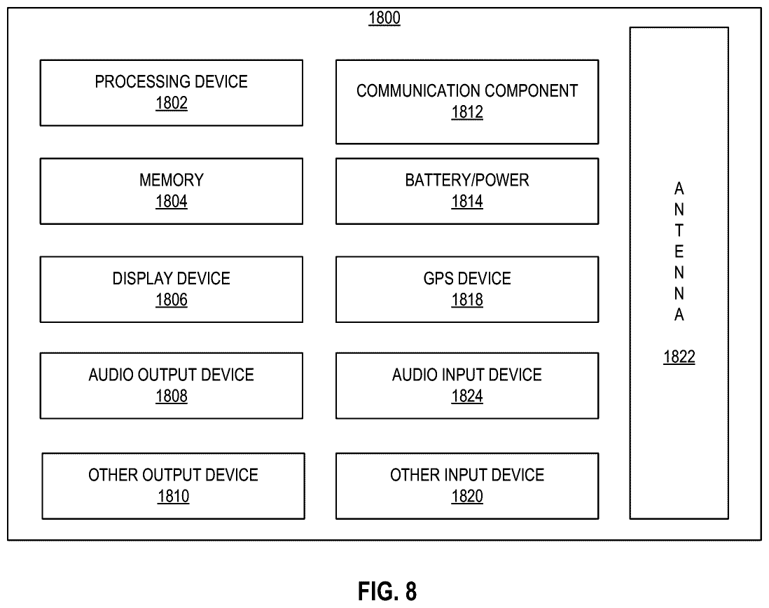

FIG. 4 is a top view of a wafer 1500 and dies 1502 that may include one or more IC structures 100 in accordance with any of the embodiments disclosed herein. The wafer 1500 may be composed of semiconductor material and may include one or more dies 1502 having IC structures formed on a surface of the wafer 1500. Each of the dies 1502 may be a repeating unit of a semiconductor product that includes any suitable IC. After the fabrication of the semiconductor product is complete, the wafer 1500 may undergo a singulation process in which the dies 1502 are separated from one another to provide discrete “chips” of the semiconductor product. The die 1502 may include one or more IC structures 100 (e.g., as discussed below with reference to FIG. 5), one or more transistors (e.g., some of the transistors of the device region 1604 of FIG. 5, discussed below) and/or supporting circuitry to route electrical signals to the transistors, as well as any other IC components. In some embodiments, the wafer 1500 or the die 1502 may include a memory device (e.g., a random-access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 8) or other logic that is configured to store information in the memory devices or execute instructions stored in the memory array.

FIG. 5 is a side, cross-sectional view of an IC device 1600 that may include one or more IC structures 100 in accordance with any of the embodiments disclosed herein. One or more of the IC structures 1600 may be included in one or more dies 1502 (FIG. 4). The IC device 1600 may include a device region 1604 including multiple IC structures 100 disclosed herein. The device region 1604 may further include electrical contacts to the gates of the transistors included in the device region 1604 (e.g., to the gate metal of the IC structures 100) and to the S/D materials of the transistors included in the device region 1604 (e.g., to the S/D regions 114 of the IC structures 100).

Electrical signals, such as power and/or input/output (I/O) signals, may be routed to and/or from the devices (e.g., the transistors) of the device region 1604 through one or more interconnect layers disposed on the device region 1604 (illustrated in FIG. 5 as interconnect layers 1606-1610). For example, electrically conductive features of the device region 1604 (e.g., the gate electrode material 108 of the IC structures 100) may be electrically coupled with the interconnect structures 1628 of the interconnect layers 1606-1610. The one or more interconnect layers 1606-1610 may form a metallization stack (also referred to as an “ILD stack”) 1619 of the IC device 1600.

The interconnect structures 1628 may be arranged within the interconnect layers 1606-1610 to route electrical signals according to a wide variety of designs (in particular, the arrangement is not limited to the particular configuration of interconnect structures 1628 depicted in FIG. 5). Although a particular number of interconnect layers 1606-1610 is depicted in FIG. 5, embodiments of the present disclosure include IC structures having more or fewer interconnect layers than depicted.

In some embodiments, the interconnect structures 1628 may include lines 1628a and/or vias 1628b filled with an electrically conductive material such as a metal. The lines 1628a may be arranged to route electrical signals in a direction of a plane that is substantially parallel with a surface of the base 102 upon which the device region 1604 is formed. For example, the lines 1628a may route electrical signals in a direction in and out of the page from the perspective of FIG. 5. The vias 1628b may be arranged to route electrical signals in a direction of a plane that is substantially perpendicular to the surface of the base 102 upon which the device region 1604 is formed. In some embodiments, the vias 1628b may electrically couple lines 1628a of different interconnect layers 1606-1610 together.

The interconnect layers 1606-1610 may include a dielectric material 1626 disposed between the interconnect structures 1628, as shown in FIG. 5. In some embodiments, the dielectric material 1626 disposed between the interconnect structures 1628 in different ones of the interconnect layers 1606-1610 may have different compositions; in other embodiments, the composition of the dielectric material 1626 between different interconnect layers 1606-1610 may be the same.

A first interconnect layer 1606 may be formed above the device region 1604. In some embodiments, the first interconnect layer 1606 may include lines 1628a and/or vias 1628b, as shown. The lines 1628a of the first interconnect layer 1606 may be coupled with contacts (e.g., contacts to the S/D regions 114 of the IC structures 100) of the device region 1604.

A second interconnect layer 1608 may be formed above the first interconnect layer 1606. In some embodiments, the second interconnect layer 1608 may include vias 1628b to couple the lines 1628a of the second interconnect layer 1608 with the lines 1628a of the first interconnect layer 1606. Although the lines 1628a and the vias 1628b are structurally delineated with a line within each interconnect layer (e.g., within the second interconnect layer 1608) for the sake of clarity, the lines 1628a and the vias 1628b may be structurally and/or materially contiguous (e.g., simultaneously filled during a dual-damascene process) in some embodiments.

A third interconnect layer 1610 (and additional interconnect layers, as desired) may be formed in succession on the second interconnect layer 1608 according to similar techniques and configurations described in connection with the second interconnect layer 1608 or the first interconnect layer 1606. In some embodiments, the interconnect layers that are “higher up” in the metallization stack 1619 in the IC device 1600 (i.e., farther away from the device region 1604) may be thicker.

The IC device 1600 may include a solder resist material 1634 (e.g., polyimide or similar material) and one or more conductive contacts 1636 formed on the interconnect layers 1606-1610. In FIG. 5, the conductive contacts 1636 are illustrated as taking the form of bond pads. The conductive contacts 1636 may be electrically coupled with the interconnect structures 1628 and configured to route the electrical signals of the transistor(s) of the device region 1604 to other external devices. For example, solder bonds may be formed on the one or more conductive contacts 1636 to mechanically and/or electrically couple a chip including the IC device 1600 with another component (e.g., a circuit board). The IC device 1600 may include additional or alternate structures to route the electrical signals from the interconnect layers 1606-1610; for example, the conductive contacts 1636 may include other analogous features (e.g., posts) that route the electrical signals to external components.

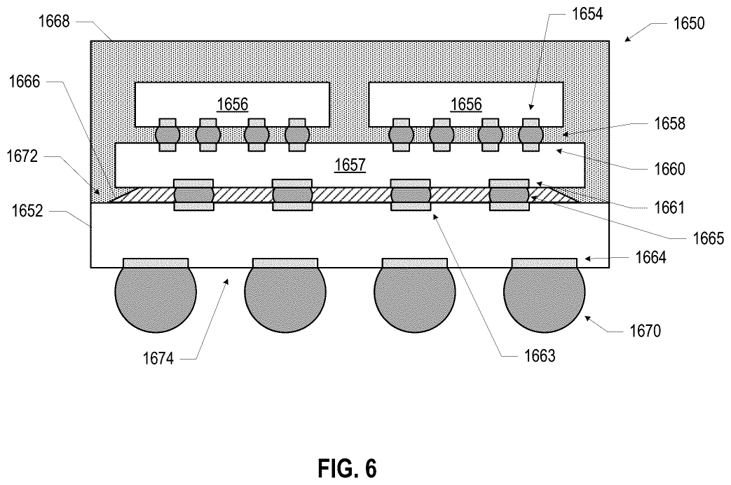

FIG. 6 is a side, cross-sectional view of an example IC package 1650 that may include one or more IC structures 100 in accordance with any of the embodiments disclosed herein. In some embodiments, the IC package 1650 may be a system-in-package (SiP).

The package substrate 1652 may be formed of a dielectric material (e.g., a ceramic, a buildup film, an epoxy film having filler particles therein, glass, an organic material, an inorganic material, combinations of organic and inorganic materials, embedded portions formed of different materials, etc.), and may have conductive pathways extending through the dielectric material between the face 1672 and the face 1674, or between different locations on the face 1672, and/or between different locations on the face 1674. These conductive pathways may take the form of any of the interconnects 1628 discussed above with reference to FIG. 5.

The package substrate 1652 may include conductive contacts 1663 that are coupled to conductive pathways (not shown) through the package substrate 1652, allowing circuitry within the dies 1656 and/or the interposer 1657 to electrically couple to various ones of the conductive contacts 1664 (or to devices included in the package substrate 1652, not shown).

The IC package 1650 may include an interposer 1657 coupled to the package substrate 1652 via conductive contacts 1661 of the interposer 1657, first-level interconnects 1665, and the conductive contacts 1663 of the package substrate 1652. The first-level interconnects 1665 illustrated in FIG. 6 are solder bumps, but any suitable first-level interconnects 1665 may be used. In some embodiments, no interposer 1657 may be included in the IC package 1650; instead, the dies 1656 may be coupled directly to the conductive contacts 1663 at the face 1672 by first-level interconnects 1665. More generally, one or more dies 1656 may be coupled to the package substrate 1652 via any suitable structure (e.g., a silicon bridge, an organic bridge, one or more waveguides, one or more interposers, wirebonds, etc.).

The IC package 1650 may include one or more dies 1656 coupled to the interposer 1657 via conductive contacts 1654 of the dies 1656, first-level interconnects 1658, and conductive contacts 1660 of the interposer 1657. The conductive contacts 1660 may be coupled to conductive pathways (not shown) through the interposer 1657, allowing circuitry within the dies 1656 to electrically couple to various ones of the conductive contacts 1661 (or to other devices included in the interposer 1657, not shown). The first-level interconnects 1658 illustrated in FIG. 6 are solder bumps, but any suitable first-level interconnects 1658 may be used. As used herein, a “conductive contact” may refer to a portion of conductive material (e.g., metal) serving as an interface between different components; conductive contacts may be recessed in, flush with, or extending away from a surface of a component, and may take any suitable form (e.g., a conductive pad or socket).

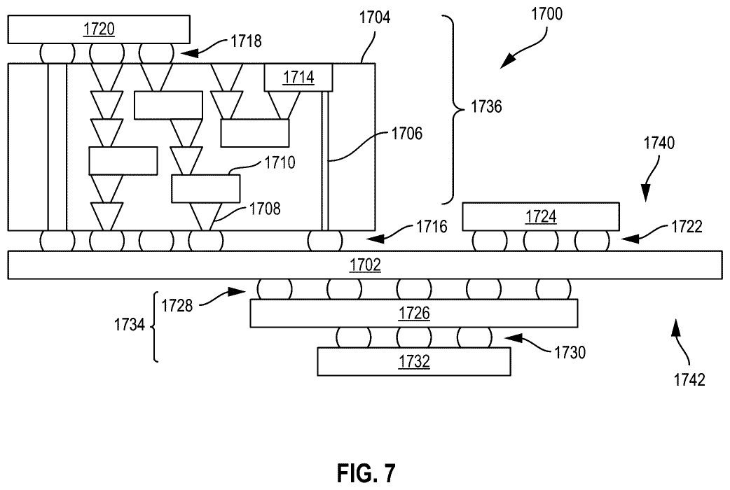

In some embodiments, an underfill material 1666 may be disposed between the package substrate 1652 and the interposer 1657 around the first-level interconnects 1665, and a mold compound 1668 may be disposed around the dies 1656 and the interposer 1657 and in contact with the package substrate 1652. In some embodiments, the underfill material 1666 may be the same as the mold compound 1668. Example materials that may be used for the underfill material 1666 and the mold compound 1668 are epoxy mold materials, as suitable. Second-level interconnects 1670 may be coupled to the conductive contacts 1664. The second-level interconnects 1670 illustrated in FIG. 6 are solder balls (e.g., for a ball grid array arrangement), but any suitable second-level interconnects 1670 may be used (e.g., pins in a pin grid array arrangement or lands in a land grid array arrangement). The second-level interconnects 1670 may be used to couple the IC package 1650 to another component, such as a circuit board (e.g., a motherboard), an interposer, or another IC package, as known in the art and as discussed below with reference to FIG. 7.

The dies 1656 may take the form of any of the embodiments of the die 1502 discussed herein (e.g., may include any of the embodiments of the IC device 1600). In embodiments in which the IC package 1650 includes multiple dies 1656, the IC package 1650 may be referred to as a multi-chip package (MCP). The dies 1656 may include circuitry to perform any desired functionality. For example, or more of the dies 1656 may be logic dies (e.g., silicon-based dies), and one or more of the dies 1656 may be memory dies (e.g., high-bandwidth memory).

Although the IC package 1650 illustrated in FIG. 6 is a flip chip package, other package architectures may be used. For example, the IC package 1650 may be a ball grid array (BGA) package, such as an embedded wafer-level ball grid array (eWLB) package. In another example, the IC package 1650 may be a wafer-level chip scale package (WLCSP) or a panel fanout (FO) package. Although two dies 1656 are illustrated in the IC package 1650 of FIG. 6, an IC package 1650 may include any desired number of dies 1656. An IC package 1650 may include additional passive components, such as surface-mount resistors, capacitors, and inductors disposed on the first face 1672 or the second face 1674 of the package substrate 1652, or on either face of the interposer 1657. More generally, an IC package 1650 may include any other active or passive components known in the art.

FIG. 7 is a side, cross-sectional view of an IC device assembly 1700 that may include one or more IC packages or other electronic components (e.g., a die) including one or more IC structures 100 in accordance with any of the embodiments disclosed herein. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742. Any of the IC packages discussed below with reference to the IC device assembly 1700 may take the form of any of the embodiments of the IC package 1650 discussed above with reference to FIG. 6 (e.g., may include one or more IC structures 100).

In some embodiments, the circuit board 1702 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

The IC device assembly 1700 illustrated in FIG. 7 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702, and may include solder balls (as shown in FIG. 7), male and female portions of a socket, an adhesive, an underfill material, and/or any other suitable electrical and/or mechanical coupling structure.

The package-on-interposer structure 1736 may include an IC package 1720 coupled to a package interposer 1704 by coupling components 1718. The coupling components 1718 may take any suitable form for the application, such as the forms discussed above with reference to the coupling components 1716. Although a single IC package 1720 is shown in FIG. 7, multiple IC packages may be coupled to the package interposer 1704; indeed, additional interposers may be coupled to the package interposer 1704. The package interposer 1704 may provide an intervening substrate used to bridge the circuit board 1702 and the IC package 1720. The IC package 1720 may be or include, for example, a die (the die 1502 of FIG. 4), an IC device (e.g., the IC device 1600 of FIG. 5), or any other suitable component. Generally, the package interposer 1704 may spread a connection to a wider pitch or reroute a connection to a different connection. For example, the package interposer 1704 may couple the IC package 1720 (e.g., a die) to a set of BGA conductive contacts of the coupling components 1716 for coupling to the circuit board 1702. In the embodiment illustrated in FIG. 7, the IC package 1720 and the circuit board 1702 are attached to opposing sides of the package interposer 1704; in other embodiments, the IC package 1720 and the circuit board 1702 may be attached to a same side of the package interposer 1704. In some embodiments, three or more components may be interconnected by way of the package interposer 1704.

In some embodiments, the package interposer 1704 may be formed as a PCB, including multiple metal layers separated from one another by layers of dielectric material and interconnected by electrically conductive vias. In some embodiments, the package interposer 1704 may be formed of an epoxy resin, a fiberglass-reinforced epoxy resin, an epoxy resin with inorganic fillers, a ceramic material, or a polymer material such as polyimide. In some embodiments, the package interposer 1704 may be formed of alternate rigid or flexible materials that may include the same materials described above for use in a semiconductor substrate, such as silicon, germanium, and other group III-V and group IV materials. The package interposer 1704 may include metal lines 1710 and vias 1708, including but not limited to through-silicon vias (TSVs) 1706. The package interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as RF devices, power amplifiers, power management devices, antennas, arrays, sensors, and microelectromechanical systems (MEMS) devices may also be formed on the package interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 7 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 8 is a block diagram of an example electrical device 1800 that may include one or more IC structures 100 in accordance with any of the embodiments disclosed herein. For example, any suitable ones of the components of the electrical device 1800 may include one or more of the IC device assemblies 1700, IC packages 1650, IC structures 1600, or dies 1502 disclosed herein. A number of components are illustrated in FIG. 8 as included in the electrical device 1800, but any one or more of these components may be omitted or duplicated, as suitable for the application. In some embodiments, some or all of the components included in the electrical device 1800 may be attached to one or more motherboards. In some embodiments, some or all of these components are fabricated onto a single system-on-a-chip (SoC) die.

Additionally, in various embodiments, the electrical device 1800 may not include one or more of the components illustrated in FIG. 8, but the electrical device 1800 may include interface circuitry for coupling to the one or more components. For example, the electrical device 1800 may not include a display device 1806, but may include display device interface circuitry (e.g., a connector and driver circuitry) to which a display device 1806 may be coupled. In another set of examples, the electrical device 1800 may not include an audio input device 1824 or an audio output device 1808, but may include audio input or output device interface circuitry (e.g., connectors and supporting circuitry) to which an audio input device 1824 or audio output device 1808 may be coupled.

The electrical device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 1800 may include a memory 1804, which may itself include one or more memory devices such as volatile memory (e.g., dynamic RAM (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded dynamic RAM (eDRAM) or spin transfer torque magnetic RAM (STT-MRAM).

In some embodiments, the electrical device 1800 may include a communication chip 1812 (e.g., one or more communication chips). For example, the communication chip 1812 may be configured for managing wireless communications for the transfer of data to and from the electrical device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1812 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1812 may operate in accordance with other wireless protocols in other embodiments. The electrical device 1800 may include an antenna 1822 to facilitate wireless communications and/or to receive other wireless communications (such as AM or FM radio transmissions).

In some embodiments, the communication chip 1812 may manage wired communications, such as electrical, optical, or any other suitable communication protocols (e.g., the Ethernet). As noted above, the communication chip 1812 may include multiple communication chips. For instance, a first communication chip 1812 may be dedicated to shorter-range wireless communications such as Wi-Fi or Bluetooth, and a second communication chip 1812 may be dedicated to longer-range wireless communications such as global positioning system (GPS), EDGE, GPRS, CDMA, WiMAX, LTE, EV-DO, or others. In some embodiments, a first communication chip 1812 may be dedicated to wireless communications, and a second communication chip 1812 may be dedicated to wired communications.

The electrical device 1800 may include battery/power circuitry 1814. The battery/power circuitry 1814 may include one or more energy storage devices (e.g., batteries or capacitors) and/or circuitry for coupling components of the electrical device 1800 to an energy source separate from the electrical device 1800 (e.g., AC line power).

The electrical device 1800 may include a display device 1806 (or corresponding interface circuitry, as discussed above). The display device 1806 may include any visual indicators, such as a heads-up display, a computer monitor, a projector, a touchscreen display, a liquid crystal display (LCD), a light-emitting diode display, or a flat panel display.

The electrical device 1800 may include an audio output device 1808 (or corresponding interface circuitry, as discussed above). The audio output device 1808 may include any device that generates an audible indicator, such as speakers, headsets, or earbuds.

The electrical device 1800 may include an audio input device 1824 (or corresponding interface circuitry, as discussed above). The audio input device 1824 may include any device that generates a signal representative of a sound, such as microphones, microphone arrays, or digital instruments (e.g., instruments having a musical instrument digital interface (MIDI) output).

The electrical device 1800 may include a GPS device 1818 (or corresponding interface circuitry, as discussed above). The GPS device 1818 may be in communication with a satellite-based system and may receive a location of the electrical device 1800, as known in the art.

The electrical device 1800 may include an other output device 1810 (or corresponding interface circuitry, as discussed above). Examples of the other output device 1810 may include an audio codec, a video codec, a printer, a wired or wireless transmitter for providing information to other devices, or an additional storage device.

The electrical device 1800 may include an other input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1800 may have any desired form factor, such as a handheld or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server device or other networked computing component, a printer, a scanner, a monitor, a set-top box, an entertainment control unit, a vehicle control unit, a digital camera, a digital video recorder, or a wearable electrical device. In some embodiments, the electrical device 1800 may be any other electronic device that processes data.

The following paragraphs provide various examples of the embodiments disclosed herein.

Example 1 provides an IC structure that includes: a stack, including a plurality of nanoribbons vertically stacked above one another; a gate electrode material enclosing the nanoribbons in a portion of the stack; a subfin replacement structure including an insulator material, where the subfin replacement structure is below and substantially aligned with a bottom nanoribbon of the stack; and an etch stop layer between the subfin replacement structure and the gate electrode material.

Example 2 provides the IC structure according to example 1, where the insulator material is a first insulator material, and the IC structure further includes a second insulator material on at least portions of sidewalls of the subfin replacement structure.

Example 3 provides the IC structure according to example 2, where the first insulator material and the second insulator material have different material compositions.

Example 4 provides the IC structure according to examples 2 or 3, where the subfin replacement structure is a trench in the second insulator material.

Example 5 provides the IC structure according to any one of examples 2-4, where the etch stop layer is further between the second insulator material and the gate electrode material.

Example 6 provides the IC structure according to example 5, further including a gate dielectric material between the etch stop layer and the gate electrode material.

Example 7 provides the IC structure according to example 6, where a portion of the etch stop layer is between the second insulator material and a portion of the gate dielectric material.

Example 8 provides the IC structure according to example 7, where a further portion of the etch stop layer is between the first insulator material and a further portion of the gate dielectric material.

Example 9 provides the IC structure according to any one of the preceding examples, where the etch stop layer is etch-selective with respect to a semiconductor material of the nanoribbons.

Example 10 provides the IC structure according to any one of the preceding examples, where the etch stop layer includes aluminum and oxygen.

Example 11 provides the IC structure according to any one of the preceding examples, where the etch stop layer has a thickness between about 1 and 10 nanometers.

Example 12 provides the IC structure according to any one of the preceding examples, where the subfin replacement structure is substantially aligned with the bottom nanoribbon of the stack in a direction that is in a plane perpendicular to a longitudinal axis of the bottom nanoribbon of the stack and is perpendicular to a vertical axis along which the nanoribbons are stacked above one another (i.e., in a direction of the x-axis of the example coordinate system shown in the present drawings).

Example 13 provides an IC structure that includes: a nanoribbon including one or more semiconductor materials; a transistor, where a channel region of the transistor includes a portion of the nanoribbon; a first layer of a gate dielectric material, where the first layer at least partially wraps around the channel region of the transistor; a gate electrode material at least partially wrapping around the first layer; a second layer of the gate dielectric material; an intermediate material; and an insulator material, where the gate electrode material is between the second layer and the first layer, the second layer is between the intermediate material and the second layer, and the intermediate material is between the insulator material and the second layer.

Example 14 provides the IC structure according to example 13, where the intermediate material includes a material that is etch-selective with respect to the one or more semiconductor materials.

Example 15 provides the IC structure according to examples 13 or 14, where the intermediate material includes a material that is etch-selective with respect to the insulator material.

Example 16 provides the IC structure according to any one of examples 13-15, where the intermediate material includes a metal and either oxygen or nitrogen.

Example 17 provides the IC structure according to any one of examples 13-16, where one side of the intermediate material is in physical contact with the second layer and another side of the intermediate material is in physical contact with the insulator material.

Example 18 provides a method of fabricating an IC structure, the method including: providing a stack of nanoribbons above a subfin, wherein the nanoribbons and the subfin include one or more semiconductor materials; depositing an etch stop layer over a top of the subfin and around portions of the nanoribbons; removing the etch stop layer from around the portions of the nanoribbons; providing a gate dielectric material around the portions of the nanoribbons and over the etch stop layer over the top of the subfin; depositing a gate electrode material around the portions of the nanoribbons; and performing an etch to remove the subfin without substantially removing the etch stop layer.

Example 19 provides the method according to example 18, where the etch stop layer includes a material that is etch-selective with respect to the subfin.

Example 20 provides the method according to examples 18 or 19, where the etch stop layer includes a material that is etch-selective with respect to the nanoribbons.

Example 21 provides the method according to any one of examples 18-20, where the IC structure is an IC structure according to any one of the preceding examples.

Example 22 provides an IC package that includes an IC die including an IC structure according to any one of examples 1-17; and a further IC component, coupled to the IC die.

Example 23 provides the IC package according to example 22, where the further IC component includes a package substrate.

Example 24 provides the IC package according to example 22, where the further IC component includes an interposer.

Example 25 provides the IC package according to example 22, where the further IC component includes a further IC die.

Example 26 provides a computing device that includes a carrier substrate and an IC structure coupled to the carrier substrate, where the IC structure is an IC structure according to any one of examples 1-17, or the IC structure is included in the IC package according to any one of examples 22-25.

Example 27 provides the computing device according to example 26, where the computing device is a wearable or handheld computing device.

Example 28 provides the computing device according to examples 26 or 27, where the computing device further includes one or more communication chips.

Example 29 provides the computing device according to any one of examples 26-28, where the computing device further includes an antenna.

Example 30 provides the computing device according to any one of examples 26-29, where the carrier substrate is a motherboard.

Example 31 provides the IC structure according to any one of examples 1-17, where the IC structure includes or is a part of a central processing unit.

Example 32 provides the IC structure according to any one of examples 1-31, where the IC structure includes or is a part of a memory device, e.g., a high-bandwidth memory device.

Example 33 provides the IC structure according to any one of examples 1-32, where the IC structure includes or is a part of a logic circuit.

Example 34 provides the IC structure according to any one of examples 1-33, where the IC structure includes or is a part of input/output circuitry.

Example 35 provides the IC structure according to any one of examples 1-34, where the IC structure includes or is a part of an FPGA transceiver.

Example 36 provides the IC structure according to any one of examples 1-35, where the IC structure includes or is a part of an FPGA logic.

Example 37 provides the IC structure according to any one of examples 1-36, where the IC structure includes or is a part of a power delivery circuitry.

Example 38 provides the IC structure according to any one of examples 1-37, where the IC structure includes or is a part of a III-V amplifier.

Example 39 provides the IC structure according to any one of examples 1-38, where the IC structure includes or is a part of PCIE circuitry or DDR transfer circuitry.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An integrated circuit (IC) structure, comprising:
a stack comprising a plurality of nanoribbons above one another;
a gate electrode material enclosing the nanoribbons in a portion of the stack;
a subfin replacement structure comprising an insulator material, wherein the subfin replacement structure is below and substantially aligned with a bottom nanoribbon of the stack; and
an etch stop layer between the subfin replacement structure and the gate electrode material.

2. The IC structure according to claim 1, wherein:
the insulator material is a first insulator material, and
the IC structure further includes a second insulator material on at least portions of sidewalls of the subfin replacement structure.

3. The IC structure according to claim 2, wherein the first insulator material and the second insulator material have different material compositions.

4. The IC structure according to claim 2, wherein the subfin replacement structure is a trench in the second insulator material.

5. The IC structure according to claim 2, wherein the etch stop layer is further between the second insulator material and the gate electrode material.

6. The IC structure according to claim 5, further comprising a gate dielectric material between the etch stop layer and the gate electrode material.

7. The IC structure according to claim 6, wherein a portion of the etch stop layer is between the second insulator material and a portion of the gate dielectric material.

8. The IC structure according to claim 7, wherein a further portion of the etch stop layer is between the first insulator material and a further portion of the gate dielectric material.

9. The IC structure according to claim 1, wherein the etch stop layer is etch-selective with respect to a semiconductor material of the nanoribbons.

10. The IC structure according to claim 1, wherein the etch stop layer includes aluminum and oxygen.

11. The IC structure according to claim 1, wherein the etch stop layer has a thickness between about 1 and 10 nanometers.

12. The IC structure according to claim 1, wherein the subfin replacement structure is substantially aligned with the bottom nanoribbon of the stack in a direction that is in a plane perpendicular to a longitudinal axis of the bottom nanoribbon of the stack and is perpendicular to a vertical axis along which the nanoribbons are stacked above one another.

13. An integrated circuit (IC) structure, comprising:
a nanoribbon comprising one or more semiconductor materials;
a transistor, wherein a channel region of the transistor includes a portion of the nanoribbon;
a first layer of a gate dielectric material, wherein the first layer at least partially wraps around the channel region of the transistor;
a gate electrode material at least partially wrapping around the first layer;
a second layer of the gate dielectric material;
an intermediate material; and
an insulator material,
wherein the gate electrode material is between the second layer and the first layer, the second layer is between the intermediate material and the gate electrode material, and the intermediate material is between the insulator material and the second layer.

14. The IC structure according to claim 13, wherein the intermediate material includes a material that is etch-selective with respect to the one or more semiconductor materials.

15. The IC structure according to claim 13, wherein the intermediate material includes a material that is etch-selective with respect to the insulator material.

16. The IC structure according to claim 13, wherein the intermediate material includes a metal and either oxygen or nitrogen.

17. The IC structure according to claim 13, wherein one side of the intermediate material is in physical contact with the second layer and another side of the intermediate material is in physical contact with the insulator material.

18. A method of fabricating an integrated circuit (IC) structure, the method comprising:
providing a stack of nanoribbons above a subfin;
depositing an etch stop layer over a top of the subfin and around portions of the nanoribbons;
removing the etch stop layer from around the portions of the nanoribbons;
providing a gate dielectric material around the portions of the nanoribbons and over the etch stop layer over the top of the subfin;
depositing a gate electrode material around the portions of the nanoribbons; and
performing an etch to remove the subfin without substantially removing the etch stop layer.

19. The method according to claim 18, wherein the etch stop layer includes a material that is etch-selective with respect to the subfin.

20. The method according to claim 19, wherein the etch stop layer includes a material that is etch-selective with respect to the nanoribbons.
